(19) United States
(12) Patent Application Publication
(10) Pub. No.: US 2013/0302930 A1
(43) Pub. Date: Nov. 14, 2013

(54) METHOD OF MANUFACTURING GALLIUM NITRIDE-BASED SEMICONDUCTOR LIGHT EMITTING DEVICE

(71) Applicant: SAMSUNG ELECTRONICS CO., LTD., Suwon-si (KR)

(72) Inventors: In Joon YEO, Hwaseong (KR); Hyun Young KIM, Yongin (KR); Sang Yeob SONG, Suwon (KR)

(73) Assignee: SAMSUNG ELECTRONICS CO., LTD., Suwon-si (KR)

(21) Appl. No.: 13/887,102

(22) Filed: May 3, 2013

(30) Foreign Application Priority Data
May 14, 2012 (KR) 10-2012-0050962

(51) Int. Cl. H01L 33/00

(52) U.S. Cl. CPC H01L 33/0075
USPC 438/46

(57) ABSTRACT

A method of manufacturing a gallium nitride (GaN)-based semiconductor light emitting device is provided. A light emitting structure is formed and includes an n-type semiconductor layer, an active layer and a p-type semiconductor layer formed of a nitride semiconductor containing gallium (Ga) on a substrate. A metal layer is disposed on the p-type semiconductor layer, and a heat treatment is performed to form a gallium(Ga)-metal compound. The gallium(Ga)-metal compound formed on the p-type semiconductor layer is removed. An electrode is disposed on an upper surface of the p-type semiconductor layer from which the gallium(Ga)-metal compound has been removed. The forming of the gallium(Ga)-metal compound includes forming a gallium vacancy in a surface of the p-type semiconductor layer.

### CROSS-REFERENCE TO RELATED APPLICATION

This application claims priority to Korean Patent Application No. 10-2012-0050962, filed on May 14, 2012, in the Korean Intellectual Property Office, the disclosure of which is incorporated herein by reference.

### TECHNICAL FIELD

The present application relates to a method of manufacturing a gallium nitride (GaN)-based semiconductor light emitting device.

### BACKGROUND

In general, a semiconductor light emitting diode (LED) has strengths as a light source in terms of high output, excellent light efficiency and reliability. Therefore, research and development to allow for the use as a high output and high efficiency light source in back light units for display devices and various illumination devices has been actively undertaken.

Such a LED is a diode emitting light through electron-hole recombination occurring at a p-n semiconductor junction due to an electrical current applied thereto and is capable of continuously emitting light using a relatively low voltage and a relatively low current and providing relatively high light emission efficiency using relatively low power. A gallium nitride-based light emitting diode is an example of a well-known diode as described above. The gallium nitride-based light emitting diode may be obtained by sequentially forming a gallium nitride (GaN)-based n-type semiconductor layer, an active layer and a p-type semiconductor layer on a substrate formed of, for example, sapphire, silicon (Si), or the like.

Since electric conductivity of a p-type GaN layer, directly related to series resistance of a device, is proportionate to positive hole doping concentration and positive hole mobility; and ohmic contact resistance is inversely proportionate to the positive hole doping concentration, there is a need to significantly improve electric conductivity and ohmic contact resistance in a p-type GaN layer in order to improve light emission efficiency by increasing energy conversion efficiency in a gallium nitride-based light emitting diode.

### SUMMARY

An aspect of the present application provides a method of manufacturing a p-type GaN layer having a relatively high electric conductivity and low ohmic contact resistance.

According to an aspect of the present application, there is provided a method of manufacturing a gallium nitride (GaN)-based semiconductor light emitting device. The method includes forming a light emitting structure including an n-type semiconductor layer, an active layer and a p-type semiconductor layer formed of a nitride semiconductor containing gallium (Ga) on a substrate. A metal layer is disposed on the p-type semiconductor layer, and a heat treatment is performed to form a gallium (Ga)-metal compound. The gallium (Ga)-metal compound formed on the p-type semiconductor layer is removed. An electrode is disposed on an upper surface of the p-type semiconductor layer from which the gallium (Ga)-metal compound has been removed. The step of forming of the gallium (Ga)-metal compound includes forming a gallium vacancy in a surface of the p-type semiconductor layer by a reaction between gallium of the p-type semiconductor layer and the metal layer.

The metal layer may be formed of a metal initially reacted with the gallium (Ga) rather than nitrogen of the p-type semiconductor layer.

The metal layer may be formed of any one selected from a group consisting of titanium (Ti), nickel (Ni) and chrome (Cr).

The metal layer may be deposited using physical vapor deposition (PVD), chemical vapor deposition (CVD), plasma laser deposition (PLD), dual-type thermal evaporation deposition, sputtering vacuum deposition, or e-beam vacuum deposition.

The heat treatment may be performed at a temperature of 300° C. or less.

The gallium (Ga)-metal compound may be removed using any one selected from a group consisting of sulfuric acid, aqua regia and a buffered oxide etchant (BOE).

The substrate may be formed of sapphire.

According to another example, there is provided a method of manufacturing a gallium nitride (GaN)-based semiconductor light emitting device. The method includes forming a light emitting structure including an first-type semiconductor layer, an active layer and a second-type semiconductor layer formed of a nitride semiconductor containing gallium (Ga) on a substrate. A metal layer is disposed on the second-type semiconductor layer, and a heat treatment is performed to form a gallium (Ga)-metal compound. The gallium (Ga)-metal compound formed on the second-type semiconductor layer is removed. An electrode is disposed on an upper surface of the second-type semiconductor layer from which the gallium (Ga)-metal compound has been removed. The step of forming of the gallium (Ga)-metal compound includes forming a gallium vacancy in a surface of the second-type semiconductor layer by a reaction between gallium of the second-type semiconductor layer and the metal layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The above and other aspects, features and other advantages of the present application will be more clearly understood from the following detailed description taken in conjunction with the accompanying drawings, in which:

FIGS. 1 to 7 are process diagrams illustrating a process of manufacturing a gallium nitride (GaN)-based semiconductor light emitting device according to an example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

In the drawings, the shapes and dimensions of elements may be exaggerated for clarity, and the same reference numerals will be used throughout to designate the same or like elements.

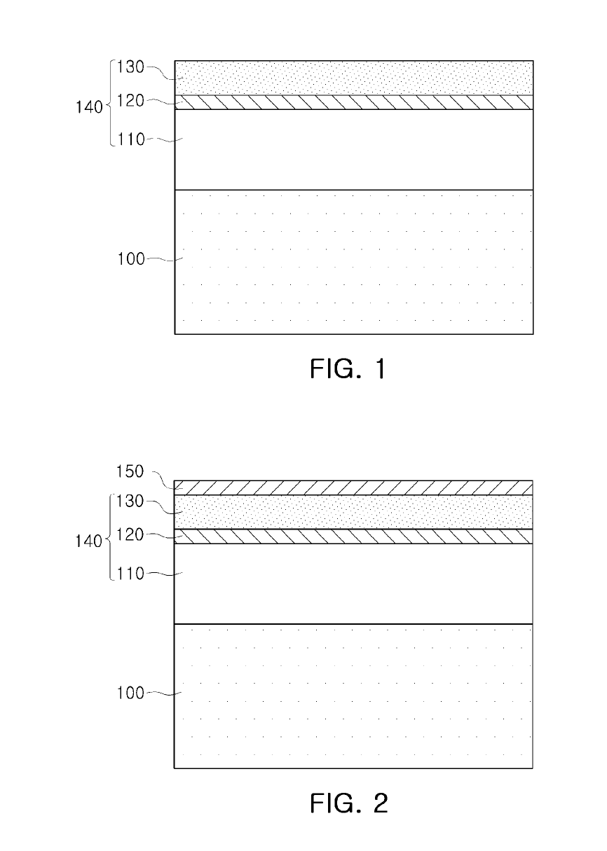

FIGS. 1 to 7 are exemplary process diagrams illustrating a process of manufacturing a gallium nitride (GaN)-based semiconductor light emitting device.

With reference to FIG. 1, a light emitting structure 140 including an n-type semiconductor layer 110, an active layer 120 and a p-type semiconductor layer 130 may be formed on a semiconductor growth substrate 100.

A semiconductor growth substrate 100 may be a substrate formed of at least one selected from a group consisting of sapphire, SiC, MgAl₂O₄, MgO, LiAlO₂, LiGaO₂, and GaN. In this case, sapphire may be a crystal having Hexa-Rhombo R3c symmetry, and may have respective lattice constants of 13.001 Å and 4.758 Å in c-axis and a-axis directions, and may have a C (0001) plane, an A (1120) plane, an R (1102) plane and the like. In this case, since the C plane comparatively facilitates the growth of a nitride thin film and is stable at relatively high temperatures, the C plane may be mainly used as a growth substrate for a nitride semiconductor.

In the present example, the n-type and p-type semiconductor layers 110 and 130 may be formed of a nitride semiconductor layer. The n-type and p-type semiconductor layers 110 and 130 may be formed of a material having a compositional formula of AlxInyGa(1-x-y)N (0≦x≦1, 0≦y≦1, and 0≦x+y≦1), for example, gallium nitride (GaN), aluminium gallium nitride (AlGaN), indium gallium nitride (InGaN), or the like. The active layer 120 formed between the n-type and p-type semiconductor layers 110 and 130 may emit light having a predetermined level of energy by the recombination of electrons and holes, and may have a multiple quantum well (MQW) structure in which a quantum well layer and a quantum barrier layer are alternately stacked. In the case of the MQW structure, for example, an InGaN/GaN structure may be used. In addition, as an n-type impurity, silicon (Si), germanium (Ge), selenium (Se), tellurium (Te), or carbon (C) may be used, and as a p-type impurity, magnesium (Mg) may be used.

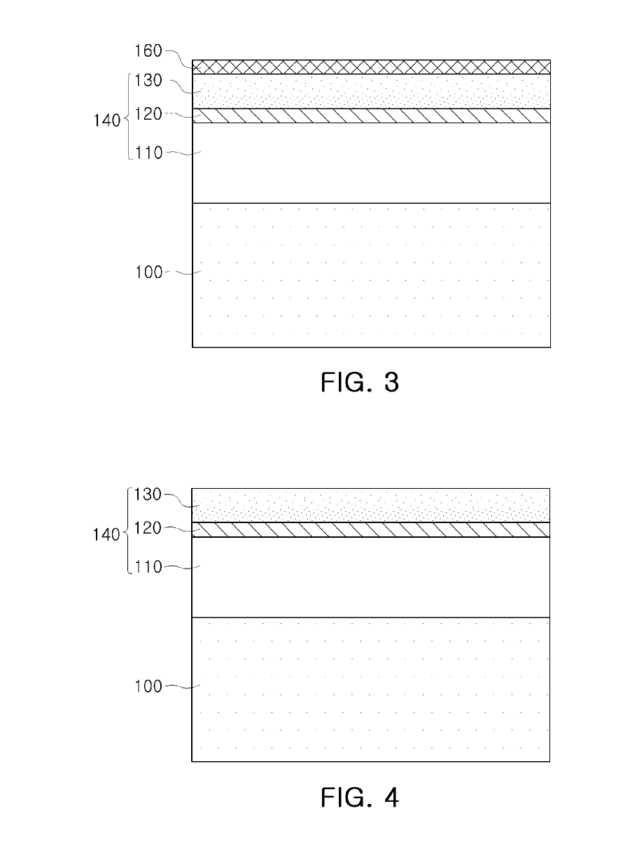

Subsequently, as shown in FIG. 2, a metal layer 150 may be disposed on the p-type semiconductor layer 130.

As a material applicable to the metal layer 150, a metal capable of increasing effective carrier condensation of the p-type semiconductor layer 130 and having good reactivity with, that is, initially reacted with ingredients except for nitrogen in a compound forming the p-type semiconductor layer 130 may be applied. For example, in a case in which a GaN-based compound is applied, a metal initially reacted with gallium (Ga), rather than nitrogen, may be applied to the metal layer 150.

In the example of the p-type semiconductor layer 130 having gallium nitride (GaN) as a principal ingredient, a gallium vacancy may be formed in a surface of the p-type semiconductor layer 130 by a reaction between gallium (Ga) of the p-type semiconductor layer 130 and the metal layer 150 through the metal layer 150 having the properties described above. Since the gallium vacancy formed in the p-type semiconductor layer 130 acts as a p-type dopant, the effective p-type carrier concentration of the surface of the p-type semiconductor layer 130 maybe increased by the reaction between the p-type semiconductor layer 130 and the metal layer 150.

The metal layer 150 capable of satisfying the conditions described above may be formed of any one selected from a group consisting of titanium (Ti), nickel (Ni) and chrome (Cr).

In addition, the metal layer 150 may be formed using various deposition methods well-known in the art, for example, physical vapor deposition (PVD), chemical vapor deposition(CVD), plasma laser deposition (PLD), dual-type thermal evaporation deposition, sputtering vacuum deposition, e-beam vacuum deposition, or the like.

Next, the light emitting structure 140, in which the metal layer 150 formed of any one selected from a group consisting of titanium (Ti), nickel (Ni) and chrome (Cr) is deposited, maybe heat treated at a temperature of 300° C. or less.

FIG. 3 illustrates a gallium(Ga)-metal compound 160 provided after the heat treatment of the metal layer 150.

Here, a surface of the p-type semiconductor layer 130 may be subjected to a heat treatment such that transformation does not occur in the active layer 120 provided under the p-type semiconductor layer 130.

In detail, the gallium (Ga)-metal compound 160 may be formed by the reaction between gallium (Ga) of the p-type semiconductor layer 130 having gallium nitride (GaN) as a principal ingredient and the metal layer 150 formed of any one selected from the group consisting of titanium (Ti), nickel (Ni) and chrome (Cr). Therefore, the gallium vacancy may be formed in the surface of the p-type semiconductor layer 130. Since the gallium vacancy formed in the p-type semiconductor layer 130 may act as a p-type dopant, the effective p-type carrier concentration on the surface of the p-type semiconductor layer 130 maybe increased by the reaction of the p-type semiconductor layer 130 and the metal.

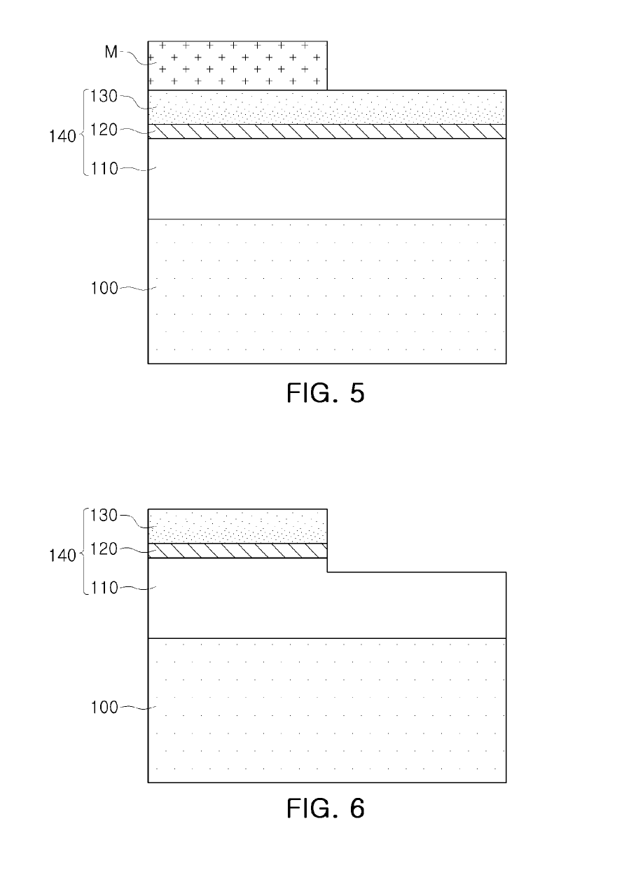

As shown in FIG. 4, the gallium (Ga)-metal compound 160 may be subsequently removed with a metal stripper such as sulfuric acid, aqua regia, a buffered oxide etchant (BOE), or the like.

In order to eliminate the gallium(Ga)-metal compound 160, a chemical for facilitating removal of a metal and preventing damage to a GaN surface may be used. FIG. 4 is a cross-sectional view illustrating the light emitting structure 140 from which the gallium (Ga)-metal compound 160 has been removed.

As shown in FIG. 5, in order to form an n-type electrode 170 by allowing for a portion of the n-type semiconductor layer 110 to be exposed, a mask pattern M may be formed on the p-type semiconductor layer 130.

The mask pattern M may be formed through a photoresist process or the like. A photoresist can have negative type properties in which a portion exposed to light through the irradiation of light thereonto does not dissolve in a developing solution; or have positive type properties in which a portion exposed to light through the irradiation of light thereonto dissolves in a developing solution.

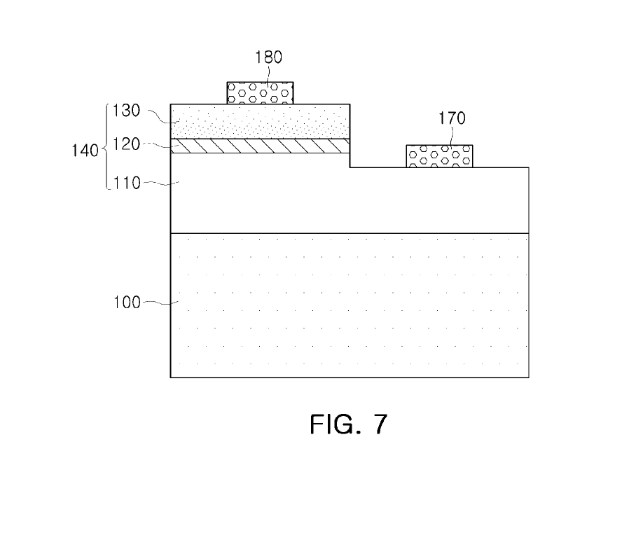

The mask pattern M, formed using the photoresist process or the like, may be formed on a partial region of the p-type semiconductor layer 130 to thus define a region of the n-type electrode 170 (FIG. 7) to be formed thereafter.

As shown in FIG. 6, a partial etching process, for example, anisotropic wet etching, may be performed to a predetermined depth in a partial region of the p-type semiconductor layer 130 and the active layer 120 by using the mask pattern M as a mask, such that the n-type semiconductor layer 110 may be exposed.

Then, the mask pattern M may be eliminated.

The gallium vacancy may be removed from a portion in which the n-type electrode 170 is to be formed, through the etching described above.

As shown in FIG. 7, when the n-type semiconductor layer 110 is exposed, the n-type electrode 170 formed of titanium (Ti) or the like may be formed on the n-type semiconductor layer 110, and a p-type electrode 180 formed of nickel or the like may be formed on the p-type semiconductor layer 130.

The gallium vacancy may be formed in the surface of the p-type semiconductor layer 130 through the process as described above, and since the gallium vacancy formed in the p-type semiconductor layer 130 may act as a p-type dopant, the effective p-type carrier concentration on the surface of the p-type semiconductor layer 130 may be increased by the reaction of the p-type semiconductor layer 130 and the metal. Thus contact resistance is reduced, such that a gallium nitride (GaN)-based semiconductor light emitting device having relatively high electric conductivity may be manufactured.

Technology of improving the crystallinity of a p-type GaN layer according to the examples of the present application may be applied to all GaN-based devices using a p-type GaN layer. The p-type GaN layer according to one example may be applied to elements such as laser diodes, hetero-junction bipolar transistors (HBTs), or the like, in which electric conductivity and ohmic contact resistance are provided as important factors, as well as to light emitting diodes.

As set forth above, according to one example, a metal layer may be deposited on a p-type GaN layer and subjected to heat treatment to form a gallium(Ga)-metal compound. The gallium(Ga)-metal compound may be removed to form a gallium vacancy in the p-type GaN layer, such that positive hole mobility and positive hole doping concentration may be increased to thus improve electric conductivity and reduce ohmic contact resistance.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

1. A method of manufacturing a gallium nitride (GaN)-based semiconductor light emitting device, the method comprising step of:
forming a light emitting structure including an n-type semiconductor layer, an active layer and a p-type semiconductor layer formed of a nitride semiconductor containing gallium (Ga) on a substrate;
forming a metal layer on the p-type semiconductor layer;
performing a heat treatment on the metal layer to form a gallium (Ga)-metal compound;
removing the gallium (Ga)-metal compound formed on the p-type semiconductor layer; and
forming an electrode on an upper surface of the p-type semiconductor layer from which the gallium (Ga)-metal compound has been removed, wherein
the step of forming the gallium (Ga)-metal compound includes forming a gallium vacancy in a surface of the p-type semiconductor layer by a reaction between gallium of the p-type semiconductor layer and the metal layer.

2. The method of claim 1, wherein the metal layer is formed of a metal initially reacted with the gallium (Ga) rather than nitrogen of the p-type semiconductor layer.

3. The method of claim 1, wherein the metal layer is an element selected from a group consisting of titanium (Ti), nickel (Ni) and chrome (Cr).

4. The method of claim 1, wherein the metal layer is deposited by way of physical vapor deposition (PVD), chemical vapor deposition (CVD), plasma laser deposition (PLD), dual-type thermal evaporation deposition, sputtering vacuum deposition, or e-beam vacuum deposition.

5. The method of claim 1, wherein the heat treatment is performed at a temperature of 300° C. or less.

6. The method of claim 1, wherein the gallium(Ga)-metal compound is removed with a metal stripper selected from a group consisting of sulfuric acid, aqua regia and a buffered oxide etchant (BOE).

7. The method of claim 1, wherein the substrate is formed of sapphire.

8. The method of claim 1, further comprising the step of:
forming a mask pattern on a first partial region of the p-type semiconductor layer.

9. The method of claim 8, further comprising the step of:
etching a second partial region of the p-type semiconductor layer and the active layer by using the mask pattern to expose an upper surface of the n-type semiconductor layer.

10. The method of claim 9, further comprising the step of:
forming an electrode on the upper surface of the n-type semiconductor layer exposed by the etching step.

11. A method of manufacturing a gallium nitride (GaN)-based semiconductor light emitting device, the method comprising step of:
forming a light emitting structure including an first-type semiconductor layer, an active layer and a second-type semiconductor layer formed of a nitride semiconductor containing gallium (Ga) on a substrate;
forming a metal layer on the second-type semiconductor layer;
performing a heat treatment on the metal layer to form a gallium (Ga)-metal compound;
removing the gallium (Ga)-metal compound formed on the second-type semiconductor layer; and
forming an electrode on an upper surface of the second-type semiconductor layer from which the gallium (Ga)-metal compound has been removed, wherein
the step of forming the gallium (Ga)-metal compound includes forming a gallium vacancy in a surface of the second-type semiconductor layer by a reaction between gallium of the second-type semiconductor layer and the metal layer.

12. The method of claim 11, wherein the metal layer is formed of a metal initially reacted with the gallium (Ga) rather than nitrogen of the second-type semiconductor layer.

13. The method of claim 11, wherein the metal layer is an element selected from a group consisting of titanium (Ti), nickel (Ni) and chrome (Cr).

14. The method of claim 11, wherein the metal layer is deposited by way of physical vapor deposition (PVD), chemical vapor deposition (CVD), plasma laser deposition (PLD), dual-type thermal evaporation deposition, sputtering vacuum deposition, or e-beam vacuum deposition.

15. The method of claim 11, wherein the heat treatment is performed at a temperature of 300° C. or less.

16. The method of claim 11, wherein the gallium(Ga)-metal compound is removed with a metal stripper selected from a group consisting of sulfuric acid, aqua regia and a buffered oxide etchant (BOE).

17. The method of claim 11, wherein the substrate is formed of sapphire.

18. The method of claim 11, further comprising the step of:
forming a mask pattern on a first partial region of the second-type semiconductor layer.

19. The method of claim 18, further comprising the step of:
etching a second partial region of the second-type semiconductor layer and the active layer by using the mask pattern to expose an upper surface of the first-type semiconductor layer.

20. The method of claim 19, further comprising the step of:
forming an electrode on the upper surface of the first-type semiconductor layer exposed by the etching step.
